(19) United States
(12) Patent Application Publication
(10) Pub. No.: US 2001/0005634 A1
(43) Pub. Date: Jun. 28, 2001

(54) Dry etching method and manufacturing method of semiconductor device for realizing high selective etching

(75) Inventor: Seiji Kajiwara, Yokohama-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 09/748,169

(22) Filed: Dec. 27, 2000

(30) Foreign Application Priority Data
Dec. 28, 1999 (JP) PATENT 11-375032

(51) Int. Cl. H01L 21/302

(52) U.S. Cl. 438/706

(57) ABSTRACT

A dry etching method using an etching gas in RIE wherein the etching gas contains CH₂F₂ at a ratio of 20% or more based on the entire volume of the etching gas. Where another carbon-containing gas is employed as an etching gas, a mixed gas containing this carbon-containing gas and CH₂F₂ is included in the etching gas at a ratio of 20% or more, and the content of CH₂F₂ is set to 5% or more.

### CROSS-REFERENCE TO RELATED APPLICATIONS

This application is based upon and claims the benefit of priority from the prior Japanese Patent Application No. 11-375032, filed Dec. 28, 1999, the entire contents of which are incorporated herein by reference.

### BACKGROUND OF THE INVENTION

This invention relates to a dry etching method and a manufacturing method of a semiconductor device, which are suitable for realizing high selective etching ratio. In particular, this invention relates to a dry etching method which is employed on the occasion of manufacturing a very fine semiconductor device.

There has been a remarkable advance in refining technique (fineness) of semiconductor device in recent years. The keys to the advancement of this refining technique are lithographic technique and etching technique, so that various researches are now being made on the exposure light source and masking material to be employed in the lithography and on the gas to be employed for the etching.

As for the etching technique, an isotropic wet etching method wherein a solution is utilized as well as an isotropic dry etching method wherein a gas is utilized have been developed more than ten years ago. Subsequently, with the advancement in refining technique of semiconductor device, a reactive ion etching (RIE: Reactive Ion Etching) exhibiting anisotropic etching has been put into practical use. Due to the development of this RIE method, it becomes possible to realize a semiconductor memory device of ultra-high density of today. While the etching technique has been modified in accordance with an advance in refining technique of semiconductor device as mentioned above, almost nothing has been changed so far with respect to the fundamental working technique for semiconductor device wherein a resist is patterned by means of lithography, and this patterned mask is employed as a mask to selectively etch an underlying material.

First of all, an etching method of semiconductor device according to the prior art will be explained with reference to FIGS. 1A and 1B, wherein a process for forming a contact hole of high aspect ratio in an interlayer insulating film by means of the RIE method is illustrated. Specifically, FIG. 1A shows a cross-sectional view of the semiconductor device where a contact hole is being formed therein, and FIG. 1B shows a cross-sectional view of the semiconductor device after the contact hole has been finished forming.

For the purpose of etching a semiconductor device, a resist 11 that has been patterned to a desired pattern is formed at first on an SiO₂ film 10 deposited in advance as an interlayer insulating film as shown in FIG. 1A. Then, by making use of this resist 11 as a mask, an etching is performed by means of the RIE method to form a contact hole. According to the prior art, an F-based gas such as CF₄ and C₂F₆, or an H—F-based gas such as CHF₃ and a mixture of CHF₃ and H₂ are usually employed as an etching gas for the SiO₂ film. As shown in FIG. 1A, in the initial stage of etching, the resist 11 functions as a mask.

However, due to the increased reduction in thickness of resist resulting from the recent trend to further increase the fineness of a semiconductor device as well as due to the recent trend to further enlarge the aspect ratio of contact hole, it becomes increasingly difficult to enable the resist to withstand against the etching until the contact hole can be completely opened. This situation is illustrated in FIG. 1B wherein the resist 11 is completely etched away during the contact hole is being formed. Since the etching mask is completely vanished in the middle of etching process, the surface of the SiO₂ film 10 which is located other than the region of forming the contact hole is also etched.

As the refining technique of a semiconductor device is further advanced as explained above, the thinning of the resist to be employed as a mask is also advanced. Therefore, during the etching process using the RIE method, the resist which is not desired to be etched is also etched away, so that it is no longer possible to enable the resist to function as a mask. This phenomenon would become more conspicuous especially on the occasion of forming a contact hole or a trench of high aspect ratio, thereby deteriorating the yield of products or the performance of the resultant semiconductor device. Therefore, it is now imperative to develop a technique to avoid any influence that might be caused due to the vanishment of the masking property of resist.

### BRIEF SUMMARY OF THE INVENTION

Therefore, an object of this invention is to provide a dry etching method and a manufacturing method of a semiconductor device, which are capable of realizing a high selective etching.

This object of the invention has been achieved by a dry etching method which comprises the steps of;

forming a recessed portion having an aspect ratio of 0.5 or more in an etching region of a layer to be etched; and

etching a portion of the layer which corresponds to the recessed portion by making use of an etching gas containing CH₂F₂;

wherein the etching gas to be employed in the etching step of the portion of the layer contains 20% or more of CH₂F₂ where carbon-containing gas in the etching gas is constituted by only CH₂F₂, or contains 5% or more of CH₂F₂ where the etching gas contains not only CH₂F₂ but also another kind of carbon-containing gas, a ratio in total of the CH₂F₂ and the another kind of carbon-containing gas in the etching gas being 20% or more.

This object of the invention has been achieved also by a dry etching method which comprises the steps of;

forming an etching mask on a layer to be etched;

forming a recessed portion having an aspect ratio of 0.5 or more in the etching mask; and

etching a portion of the layer which corresponds to the recessed portion by making use of an etching gas containing CH₂F₂;

wherein the etching gas to be employed in the etching step of the portion of the layer contains 20% or more of CH₂F₂ where carbon-containing gas in the etching gas is constituted by only CH₂F₂, or contains 5% or more of CH₂F₂ where the etching gas contains not only CH₂F₂ but also another kind of carbon-containing gas, a ratio in total of the CH₂F₂ and the another kind of carbon-containing gas in the etching gas being 20% or more.

This object of the invention has been achieved also by a dry etching method which comprises the steps of;

forming an etching mask on a layer to be etched;

forming a recesses portion reaching through the etching mask to the middle of the layer to be etched, and having an aspect ration of 0.5 or more; and

etching a portion of the layer which corresponds to the recessed portion by making use of an etching gas containing CH₂F₂;

wherein the etching gas to be employed in the etching step of the portion of the layer contains 20% or more of CH₂F₂ where carbon-containing gas in the etching gas is constituted by only CH₂F₂, or contains 5% or more of CH₂F₂ where the etching gas contains not only CH₂F₂ but also another kind of carbon-containing gas, a ratio in total of the CH₂F₂ and the another kind of carbon-containing gas in the etching gas being 20% or more.

This object of the invention has been achieved also by a method of manufacturing a semiconductor device, which comprises the steps of;

forming a first mask on a semiconductor substrate;

forming a second mask on the first mask;

forming a recessed portion having an aspect ratio of 0.5 or more in the second mask;

etching a portion of the first mask which corresponds to the recessed portion by making use of an etching gas containing CH₂F₂; and

etching a portion of the semiconductor substrate which corresponds to the recessed portion to thereby form a trench;

wherein the etching gas to be employed in the etching step of the portion of the first mask contains 20% or more of CH₂F₂ where carbon-containing gas in the etching gas is constituted by only CH₂F₂, or contains 5% or more of CH₂F₂ where the etching gas contains not only CH₂F₂ but also another kind of carbon-containing gas, a ratio in total of the CH₂F₂ and the another kind of carbon-containing gas in the etching gas being 20% or more.

This object of the invention has been achieved also by a method of manufacturing a semiconductor device, which comprises the steps of;

forming a gate insulating film on a semiconductor substrate;

forming a gate electrode on the gate insulating film;

forming an insulating film on the gate insulating film and on the gate electrode;

forming an interlayer insulating film on the insulating film;

forming a contact hole to a depth to reach a portion of the insulating film which is located between the gate electrodes neighboring to each other by making use of the insulating film as a stopper; and

etching a portion of the insulating film which is disposed between the gate electrodes by making use of an etching gas containing CH₂F₂;

wherein the etching gas to be employed in the etching step of the portion of insulating film which is disposed between the gate electrodes contains 20% or more of CH₂F₂ where carbon-containing gas in the etching gas is constituted by only CH₂F₂, or contains 5% or more of CH₂F₂ where the etching gas contains not only CH₂F₂ but also another kind of carbon-containing gas, a ratio in total of the CH₂F₂ and the another kind of carbon-containing gas in the etching gas being 20% or more.

This object of the invention has been achieved also by a method of manufacturing a semiconductor device, which comprises the steps of;

forming an interlayer insulating film on a semiconductor substrate;

forming a mask on the interlayer insulating film;

etching the mask to form a desired pattern thereof; and

forming a contact hole by etching the interlayer insulating film by making use of the mask;

wherein at least part of the step of forming a contact hole by etching the interlayer insulating film is performed by an etching employing an etching gas containing CH₂F₂; and the etching gas to be employed in the etching step employing an etching gas containing CH₂F₂ contains 20% or more of CH₂F₂ where carbon-containing gas in the etching gas is constituted by only CH₂F₂, or contains 5% or more of CH₂F₂ where the etching gas contains not only CH₂F₂ but also another kind of carbon-containing gas, a ratio in total of the CH₂F₂ and the another kind of carbon-containing gas in the etching gas being 20% or more.

According to the aforementioned methods, CH₂F₂ is employed as an etching gas in the dry etching process such as the RIE process on the occasion of forming a trench or a contact hole. Thus, due to the employment of this etching gas containing CH₂F₂, only the region desired to be etched can be selectively etched, while preventing the etching of the mask which is not desired to be etched and contrary, allowing reaction products from the RIE to be deposited on the mask, thus preventing the etching of the mask. Therefore, even if the aspect ratio is enormously large or even if the film thickness of mask is very thin, it is possible to ensure a sufficiently large or substantially infinitely etching selectivity. Thus, it is possible according to this invention to provide a dry etching method and a manufacturing method of a semiconductor device, which are suitable for realizing a high selective etching.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIGS. 1A and 1B respectively illustrate a cross-sectional view of a semiconductor device for explaining a dry etching method according to the prior art;

FIG. 2 is a diagram schematically illustrating an RIE apparatus for performing a dry etching according to a first embodiment of this invention;

FIGS. 3A and 3B are cross-sectional views sequentially illustrating the manufacturing steps for forming a contact hole by means of a dry etching method according to a first embodiment of this invention;

FIGS. 4A and 4B are cross-sectional views sequentially illustrating the manufacturing steps for forming a contact hole by means of a dry etching method according to a second embodiment of this invention;

FIGS. 5A and 5B are cross-sectional views sequentially illustrating the manufacturing steps for forming a contact hole by means of a dry etching method according to a third embodiment of this invention;

FIG. 6 is a graph illustrating the etching rates of the bottom face of contact hole and of the surface of SiO₂ film in the RIE wherein various kinds of etching gas were employed;

FIGS. 7A to 7G respectively shows a cross-sectional view sequentially illustrating the manufacturing process of a semiconductor device according to a first embodiment of this invention;

FIGS. 8A to 8F respectively shows a cross-sectional view sequentially illustrating the manufacturing process of a semiconductor device according to a second embodiment of this invention;

FIGS. 9A to 9E respectively shows a cross-sectional view sequentially illustrating the manufacturing process of a semiconductor device according to a third embodiment of this invention;

FIGS. 10A and 10B respectively shows a cross-sectional view sequentially illustrating the manufacturing process of a semiconductor device according to a modified example of the third embodiment of this invention;

FIGS. 11A to 11C respectively shows a cross-sectional view of a semiconductor device for explaining the effects to be caused when the flow rate of gas is altered;

FIG. 12 is a graph illustrating a relationship between the deposition rate of reaction products and the ratio of a mixed gas consisting of a carbon-containing gas and CH₂F₂ to a total of an etching gas;

FIGS. 13A to 13C respectively shows a cross-sectional view of a semiconductor device for explaining the effects to be caused when the flow rate of gas is altered;

FIGS. 14A to 14C respectively shows a cross-sectional view of a semiconductor device for explaining the effects to be caused when high-frequency power and the pressure inside the chamber are altered; and

FIG. 15 is a graph illustrating the relationship of the deposition rate of reaction products relative to the high-frequency power and the pressure inside the chamber.

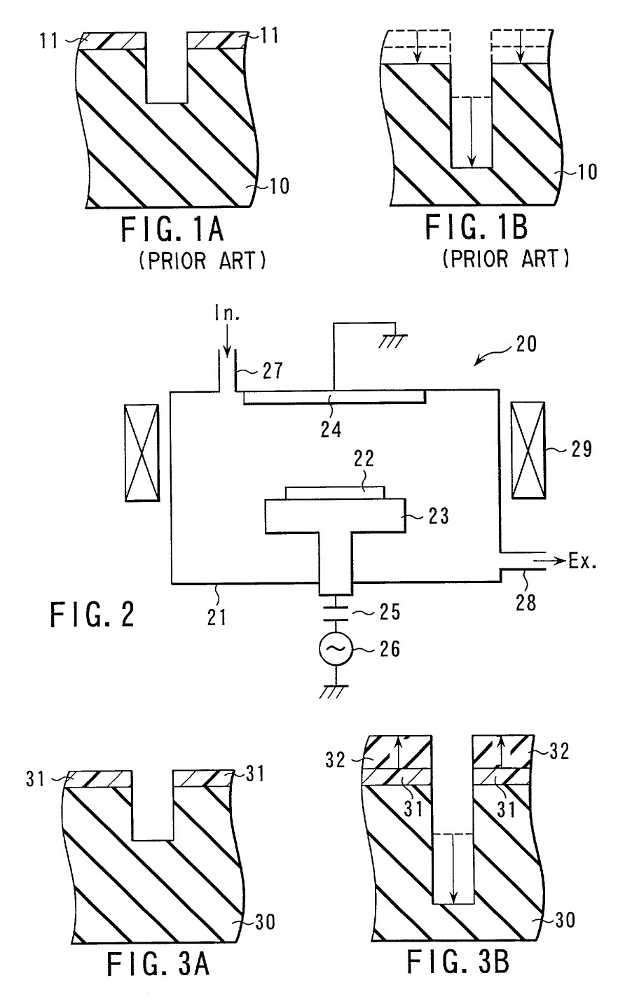

### DETAILED DESCRIPTION OF THE INVENTION

FIG. 2 is a diagram schematically illustrating a dry etching apparatus, in particular, a magnetron RIE apparatus, which is employed for explaining the dry etching according to a first embodiment of this invention.

Referring to FIG. 2, this magnetron RIE apparatus 20 comprises, as an etching chamber, a vacuum chamber 21 in which a mounting table 23 (high-frequency electrode) for mounting a substance to be treated (hereinafter referred to as a treating substance) such as a semiconductor wafer, etc. and a ground electrode 24 grounded and disposed to face the mounting table 23 are housed. On the outside of the vacuum chamber 21, there are disposed a high-frequency power source 26 for applying a high-frequency power via a blocking capacitor 25 to the mounting table 23, a gas inlet pipe 27 for introducing an etching gas into the vacuum chamber 21, a gas outlet pipe 28 for discharging the etching gas, and a magnet 29 surrounding the vacuum chamber 21 for producing a magnetic field inside the vacuum chamber 21. A specific example of the magnet 29 is an electromagnetic coil.

Next, a method of etching by means of this magnetron RIE apparatus 20 constructed as described above will be explained with reference to FIGS. 3A and 3B which show cross-sectional views illustrating the manufacturing process for forming a contact hole in an interlayer insulating film. Specifically, FIG. 3A shows a cross-sectional view where a contact hole is being formed therein, and FIG. 3B shows a cross-sectional view after the contact hole has been finished forming.

First of all, a SiO₂ film 30 is formed as an interlayer insulating film on the surface of a semiconductor wafer, and then, a resist 31 is coated on the SiO₂ film 30. The resist 31 is then subjected to exposure and development treatments to thereby form a desired pattern of the resist 31. Thereafter, the resultant semiconductor wafer is mounted as the treating substance 22 on the mounting table 23 disposed inside the vacuum chamber 21.

Subsequently, the atmosphere inside the vacuum chamber 21 is evacuated by means of a vacuum pump (not shown), after which an etching gas is introduced from the gas inlet pipe 27 into the vacuum chamber 21. Then, a high-frequency power is applied onto the mounting table 23 by means of the high-frequency power source 26. As a result of this application of high-frequency power, a high-density plasma is caused to generate in the vacuum chamber 21 under the influence of the magnet 29, thereby producing ions and electrons. Under the influence of high-frequency power, the electrons are forced to move toward the high-frequency power source 26 on the occasion when the high-frequency power is positive, thereby negatively electrifying the blocking capacitor 25. On the contrary, when the high-frequency power is negative, the electrons are forced to move toward the ground electrode 24 so as to be vanished. On this occasion, although the ions are actuated together with electrons, the ions have lower mobility as compared with electrons, so that ions are incapable of impinging against the high-frequency electrode or against the ground electrode. Therefore, the interior of the plasma can be settled in a positively electrified state due to the deficiency slightly of electrons. As a result, an electric field is caused to generate in a space between the high-frequency electrode 23 (blocking capacitor 25) and the plasma. Accordingly, ions having a positive electric charge are forced to move toward the high-frequency electrode 23 that has been negatively charged by the electrons and to anisotropically impinge against the high-frequency electrode 23. As a result of this impingement by the ions, the etching of the treating substance 22 can be executed.

As for the etching gas to be employed in the beginning on the occasion of this etching process, an F-based gas such as CF₄ and C₂F₆, or an H—F-based gas such as CHF₃ and a mixture of CHF₃ and H₂, which are commonly employed as an etching gas for SiO₂, are employed. By means of the RIE method where the aforementioned gas is employed as an etching gas, the SiO₂ film 30 is etched away using the resist 31 as a mask. As a result of this etching, it is possible to form a contact hole having an aspect ratio of 0.5 or so as shown in FIG. 3A. When the aspect ratio of contact hole is around this range, the thinning of resist can be disregarded.

Then, the etching gas is switched from the aforementioned gas to CH₂F₂ and the etching by means of the RIE method using this CH₂F₂ is continued. In this etching, although the etching is permitted to proceed at the bottom of the contact hole that has been formed in advance, the etching of the upper surface of the resist 31 is prevented from proceeding due to the phenomenon that reaction products 32 produced from the RIE are caused to deposit on the surface of the resist 31. Accordingly, it is now possible to form a contact hole without inviting the vanishment of the masking property of resist 31.

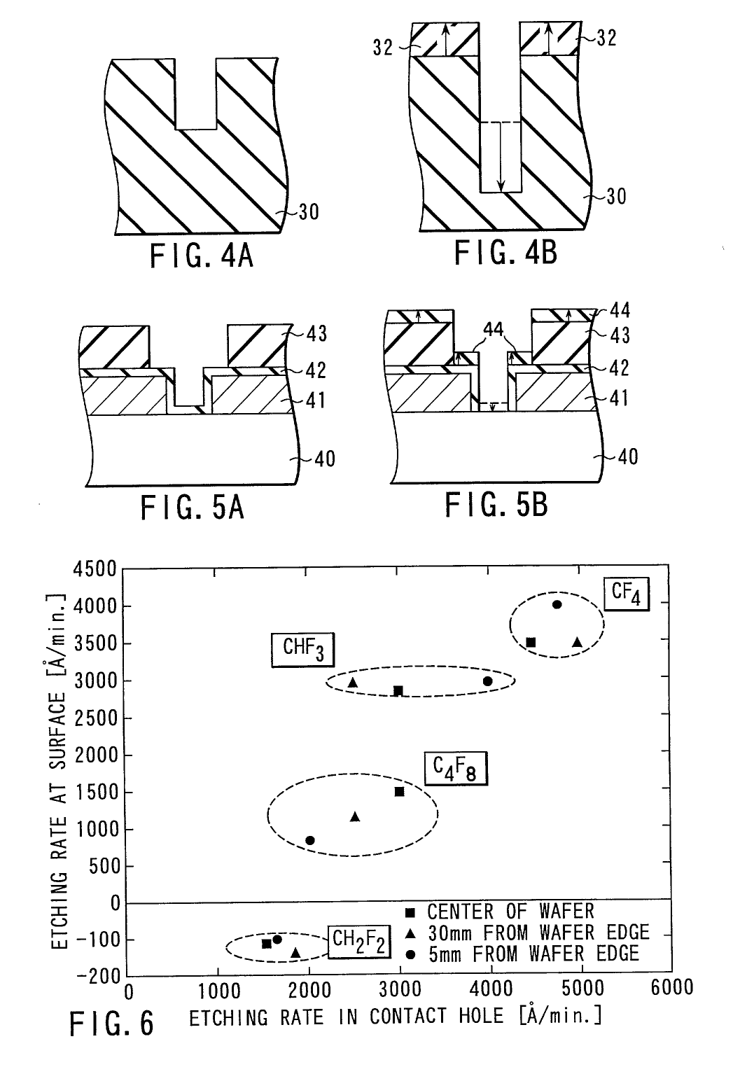

Next, the dry etching method according to the second embodiment of this invention will be explained with reference to FIGS. 4A and 4B which show cross-sectional views illustrating the process for forming a contact hole by a dry etching using a dry etching apparatus shown in FIG. 2 as in the case of the first embodiment. Specifically, FIG. 4A shows a cross-sectional view of a semiconductor device where a contact hole is being formed therein, and FIG. 4B shows a cross-sectional view of a semiconductor device after the contact hole has been finished forming.

First of all, as shown in FIG. 4A, by means of the RIE method employing, as an etching gas, an F-based gas such as CF₄ and C₂F₆, or an H—F-based gas such as CHF₃ and a mixture of CHF₃ and H₂, the SiO₂ film 30 is etched away. As a result of this etching, a contact hole having an aspect ratio of 0.5 or so is formed. Thereafter, the resist is completely removed.

Then, the etching gas is switched from the aforementioned gas to CH₂F₂ and the etching by means of the RIE method using this CH₂F₂ is continued. In this etching, although the etching is permitted to proceed at the bottom of the contact hole as shown in FIG. 4B, the etching of the upper surface of the SiO₂ film 30 is prevented from proceeding due to the deposition of reaction products 32 produced from the RIE on the surface of the SiO₂ film 30. Namely, in spite of the fact that the aforementioned upper surface and the bottom of the contact hole are both formed of the same material, the etching of the bottom of the contact hole is proceeded with a high selectivity relative to the aforementioned upper surface.

Next, the dry etching method according to the third embodiment of this invention will be explained with reference to FIGS. 5A and 5B which show cross-sectional views illustrating the process for forming a contact hole having a stepped portion therein by a dry etching using an apparatus shown in FIG. 2 as in the case of the first embodiment. Specifically, FIG. 5A shows a cross-sectional view of a semiconductor device where a contact hole is being formed therein, and FIG. 5B shows a cross-sectional view of a semiconductor device after the contact hole has been finished forming.

As shown in FIG. 5A, a gate electrode 41 is formed on a semiconductor substrate 40, and an SiN film 42 is deposited on the surfaces of the gate electrode 41 and the semiconductor substrate 40. Further, an SiO₂ film 43 is formed on the SiN film 42. For the purpose of forming a contact hole having a depth reaching the semiconductor substrate 40, a portion of the SiO₂ film 43 disposed between the gate electrodes 41 neighboring to each other is etched away. On this etching process, the SiN film 42 functions as an etching stopper.

In the next step, the portion of the SiN film 42 which is disposed between the neighboring gate electrodes 41 is removed by means of the RIE method employing CH₂F₂ as an etching gas. In this etching, as shown in FIG. 5B, although only the portion of the SiN film 42 which is disposed between the gate electrodes 41 is permitted to be etched away, but due to the deposition of reaction products 44 produced from the RIE on the surface of the SiO₂ film 43 as well as on the surface of the SiN film 42 deposited on the gate electrode 41, the etching of these surfaces is prevented from proceeding.

As explained with reference to the dry etching methods according to the aforementioned first to third embodiments, when an etching is performed by means of the RIE method where CH₂F₂ is employed as an etching gas, only the region which is disposed at a lowest level in a stepped configuration is permitted to be selectively etched, while preventing the etching of other regions from proceeding due to the deposition of the reaction products as mentioned above.

This phenomenon can be attributed to the reaction of gases in the step of RIE. An F-based gas such as CF₄ and C₂F₆, or an H—F-based gas such as CHF₃ and a mixture of CHF₃ and H₂, which are conventionally employed, can be brought into a state of plasma in the vacuum chamber 21 under the influence of magnetron discharge to be generated by a high-frequency power, thereby generating ions and radicals therein. The life of the ions and the contributory ratio of ions to the etching can be graded as: CF₃⁺> CF₂⁺> CF₃⁺> C. On the other hand, the contributory ratio of radicals to the etching can be graded as: CF₃* > CF₂* > CF₃* > C. In this case, the lower the contributory ratio to the etching is, the more easy it becomes for the reaction products to deposit.

In the cases of the F-based gas such as CF₄ and C₂F₆ that have been conventionally employed, the decomposition of gas can hardly take place in the plasma, so that active species such as CF₄⁺and CF₃⁺, or CF₄* and CF₃*, which are high in contributory ratio to the etching, are predominantly produced, while unsaturated species such as CF (Fluoro-Carbon) and C (carbon), which are low in contributory ratio to the etching, can be hardly produced. The same phenomenon as described above can be seen also in the H—F-based gas such as CHF₃ and therefore, since the unsaturated species can be hardly produced, the deposition of reaction products such as CF and C can hardly take place.

By contrast, when CH₂F₂ is employed as an etching gas, the unsaturated species can be easily produced, thus making it possible to utilize the unsaturated species as a precursor for promoting the deposition of reaction products. Namely, the unsaturated species function so as to suppress the etching. Further, in concurrent with the generation of the unsaturated species, active species functioning as an etchant are also caused to generate. Since the unsaturated species such as CF⁺and C are short in life, they are turned into reaction products as they are impinged against the surface of the treating substance, and then, deposited thereon.

On the other hand, since the active species such as CF₃⁺and CF₂⁺are relatively long in life, they can penetrate deep into the treating substance, thereby selectively etching only the bottom portion of the trench or contact hole. Of course, the surface of the treating substance is also exposed to the active species which are capable of contributing to the etching. However, due to the predominant number of unsaturated species existing on the surface of treating substance, the etching action by the active species on this surface is overwhelmed by the deposition of the reaction products produced by the unsaturated species. As a result, due to this deposition of the reaction products produced by the unsaturated species, the surface of the treating substance is prevented from being etching, while allowing the etching of only the bottom portion of the trench to proceed by the action of the active species. Of course it is possible to accurately control the generation ratio between the active species and the unsaturated species by suitably adjusting the etching conditions.

FIG. 6 is a graph illustrating the etching rates of the bottom face of contact hole and of the surface of SiO₂ film in the formation of contact holes by means of the RIE wherein various kinds of etching gas were employed. The square solid marks in FIG. 6 indicate the etching rate at the central portion of a semiconductor wafer, the triangular solid marks indicate the etching rate at the portion of the semiconductor wafer which is located 30 mm from the edge of the semiconductor wafer, and the circular solid marks indicate the etching rate at the portion of the semiconductor wafer which is located 5 mm from the edge of the semiconductor wafer. By the way, all of the etching conditions except the kinds of etching gas were the same in all of these experiments.

As seen from FIG. 6, in the cases of etching where CF₄, CHF₃ and C₄F₈ were respectively employed as an etching gas, the etching was proceeded not only at the bottom face of the contact hole but also at the surface of the SiO₂ film though there was some degree of difference in etching rate among them. Whereas, in the case of etching where CH₂F₂ was employed as an etching gas, the etching rate on the surface of the SiO₂ film was approximately minus 100 angstroms/min. though the etching rate inside the contact hole was somewhat decreased. Namely, the surface of the SiO₂ film was not etched at all, and on the contrary, was deposited with a material, thus suggesting that the selective etching ratio was substantially infinite at this moment.

By the way, as for the RIE apparatus, although a magnetron RIE apparatus was exemplified in the foregoing explanation, it is of course possible to employ other kinds of RIE apparatus. For example, it is possible to employ the ECR (Electron Cyclotron Resonance) etching apparatus where electron cyclotron resonance is utilized for generating a high-density plasma under the influences of magnetic field and microwave, a helicon wave etching apparatus which is capable of generating a high-density plasma through an interaction between helicon wave and electrons, or an inductively coupled plasma etching apparatus which is designed to generate a plasma by accelerating electrons by means of induced electric field to be generated by a high-frequency induced magnetic field.

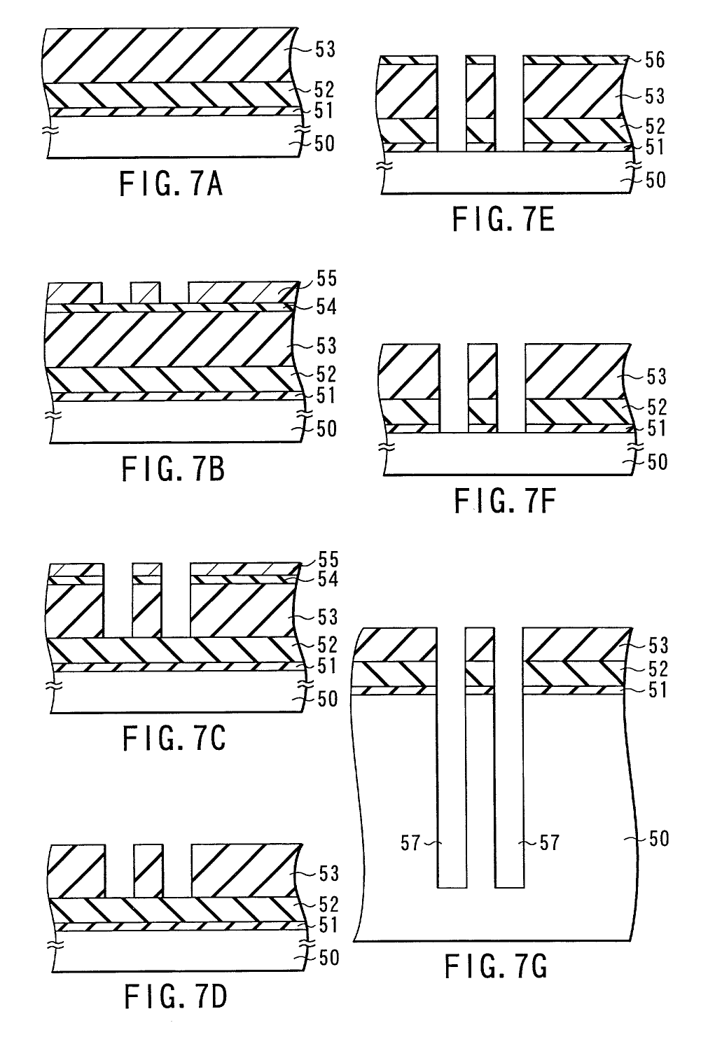

Next, a first embodiment of manufacturing a semiconductor device by making use of the aforementioned dry etching method will be explained with reference to FIGS. 7A to 7G which illustrate one example of the method of manufacturing a trench capacitor of DRAM (Dynamic Random Access Memory).

First of all, as shown in FIG. 7A, an SiO₂ film 51 is formed on a semiconductor substrate 50 (for example, a silicon substrate) by means of hydrogen combustion oxidation method. Then, an SiN film 52 and an SiO₂ film 53 are deposited on this SiO₂ film 51 by means of a CVD (Chemical Vapor Deposition) method.

Then, as shown in FIG. 7B, an anti-reflective coating (ARC) 54 is formed on the SiO₂ film 53 by making use of an organic material. Thereafter, a resist 55 is coated on this ARC 54 and then, subjected to a PEP (Photo Engraving Process) to obtain a resist pattern having openings at predetermined regions for forming a capacitor.

Then, as shown in FIG. 7C, the ARC 54 and the SiO₂ film 53 existing in the predetermined regions for forming a trench capacitor are selectively removed by means of the RIE method using the resist 55 as a mask. On this occasion, an F-based gas such as CF₄ and C₂F₆, or an H—F-based gas such as CHF₃ and a mixture of CHF₃ and H₂ which are usually employed for etching SiO₂ can be employed as an etching gas for this RIE. The reason why the SiN film 52 is not removed together with the removal of the ARC 54 and the SiO₂ film 53 is that since the resist 55 is formed very thin now due to an increased fineness of semiconductor device for enhancing the density of memory capacity of DRAM, if the SiN film 52 is etched away together with the SiO₂ film 53, the masking property of the resist 55 may be lost during this etching process.

Thereafter, the resist 55 and the ARC 54 are ashed away using an ashing process as shown in FIG. 7D, which is followed by a wet etching process for completely removing any residuals of the resist 55 and the ARC 54 which might be left remained in the previous step. As for the etchant to be employed in this wet etching, a mixed solution comprising H₂SO₄, H₂O₂ and H₂O can be employed for instance.

Then, as shown in FIG. 7E, the SiN film 52 and the SiO₂ film 51 are etched away using the SiO₂ film 53 as a mask by means of the RIE method using the magnetron RIE apparatus shown in FIG. 2.

In this step, instead of the aforementioned F-based gas, or the H—F-based gas such as CHF₃ and a mixture of CHF₃ and H₂ which are conventionally employed in the RIE method for etching SiO₂, or instead of the gas such as CF₄, CHF₃ and ArO₂ which are conventionally employed for etching SiN, a different kind of gas such as CH₂F₂ is employed as an etching gas. However, the other etching conditions may be the same as those conventionally employed, i.e. 10-100 sccm in gas flow rate; 10-100 mTorr in gas pressure; 400-2000W in high-frequency power; and 30-60°C. in substrate temperature.

When the RIE is performed using this CH₂F₂ as an etching gas, the exposed portions of SiN film 52 and SiO₂ film 51 can be successively etched without etching the SiO₂ film 53 functioning as a mask. On the contrary, reaction products 56 during the RIE are allowed to deposit on the surface of the SiO₂ film 53. The reaction products 56 to be generated in this case are C (carbon), CF, etc. Namely, when the RIE is performed using this CH₂F₂ as an etching gas, it will bring about a phenomenon that the reaction products are allowed to deposit on the surface of the mask while allowing the etching to proceed at only the openings of mask, i.e. the regions which are desired to be etched, thus realizing a substantially infinite selective etching ratio.

Thereafter, the reaction products 56 are removed as shown in FIG. 7F by means of ashing and wet etching.

Subsequently, as shown in FIG. 7G, the etching of the semiconductor substrate 50 is performed by means of the RIE method using the SiO₂ film 53 as a mask to thereby form a trench 57 for the cell capacitor.

CH₂F₂ may be employed as an etching gas on this occasion of forming the trench 57 in the semiconductor substrate 50 by means of the RIE method. However, it is more preferable, in view of the etching rate and controllability, to employ a gas comprising CF₄, SF₆ or CF₄, which are conventionally employed as an etching gas for etching Si, and an additional component of Cl (chlorine) or Br (bromine), which are included in the gas by substituting them for some of Fs of CF₄.

Thereafter, the SiO₂ film 53 is removed by means of a wet etching for instance, and then, an insulating film containing impurities therein is formed inside the trench 57 and heat-treated to allow the impurities included in the insulating film to diffuse (solid phase diffusion) into the semiconductor substrate 50, thereby forming an impurity diffusion layer around the trench 50, the impurity diffusion layer being subsequently turned into a plate electrode. Then, the insulating film is removed, and a capacitor insulating film is formed on the inner wall of the trench 50. As for the materials for this capacitor insulating film, it is possible to employ an SiO₂ film, an ONO film (a 3-ply structure consisting of an SiO₂ film, an SiN film and an SiO₂ film), or ON film (a 2-ply structure consisting of an SiO₂ film and an SiN film). Thereafter, the trench 57 is filled for example with a polycrystalline silicon film for forming a storage node electrode, thereby accomplishing a cell capacitor.

The aspect ratio of the trench for cell capacitor is generally very large. For example, in the case of a DRAM having a memory capacity in the order of 256 Mbit, the aspect ratio thereof would be as large as about 20. Further, it is expected in the case of a DRAM of 1 Gbit that the aspect ratio of trench thereof would become more than 20 in view of securing a sufficient capacity of cell capacitor.

If a trench having such a high aspect ratio is to be formed in a substrate, the film thickness of the mask is generally required to be increased in view of the large consumption of the mask during the etching as well as in view of the etching of the mask due to the vanishing of the resist during the patterning of the mask.

Whereas, according to the manufacturing method of semiconductor device as explained in this embodiment, the etching on the occasion of forming the mask is performed by means of the RIE method employing CH₂F₂ as an etching gas. As a result, it is possible to bring about a phenomenon that the etching takes place only at the regions which are desired to be etched, while not allowing the etching to proceed at the surface of mask. As a result, the film thickness of the mask can be set to such a minimum thickness that enables the trench of cell capacitor to be formed.

Further, if CH₂F₂ is employed also in the RIE on the occasion of forming the trench of cell capacitor, even though the etching rate may be somewhat decreased, the mask is no longer required to be extraordinarily thickened, and it is possible to form a cell capacitor having a high reliability since there is little possibility of vanishing the mask.

After the formation of this trench type cell capacitor, an element isolation region is formed in the memory cell array region as well as in the peripheral circuit region of the semiconductor substrate 50 by means of STI (Shallow Trench Isolation). This STI technique is designed such that a shallow trench is formed at first in a semiconductor substrate and then, the trench is filled with an insulating material to thereby form an element isolation region. However, even this trench which is designed to be utilized for forming the element isolation region may be formed by making use of the same procedure as employed for forming the aforementioned trench 57 of cell capacitor.

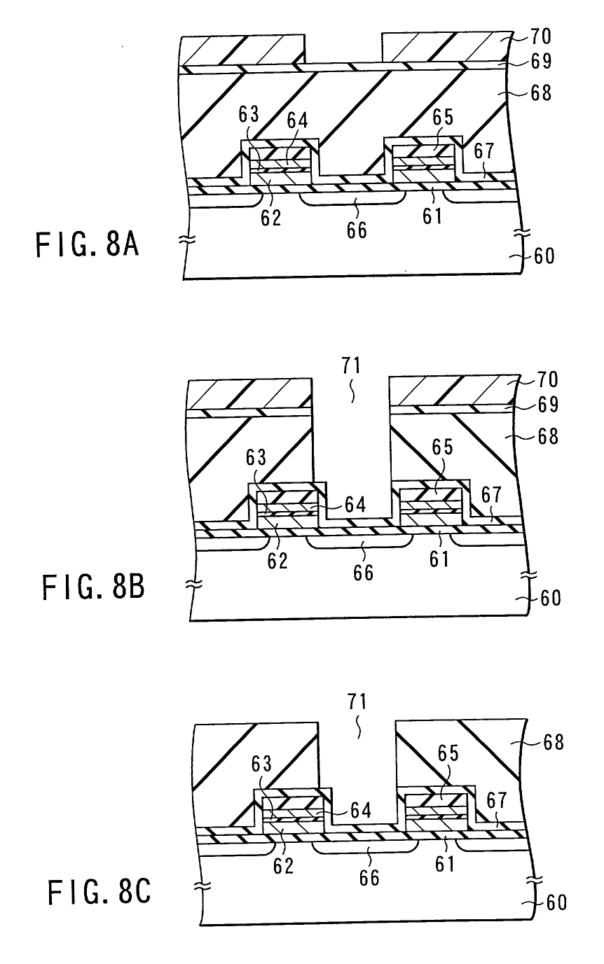

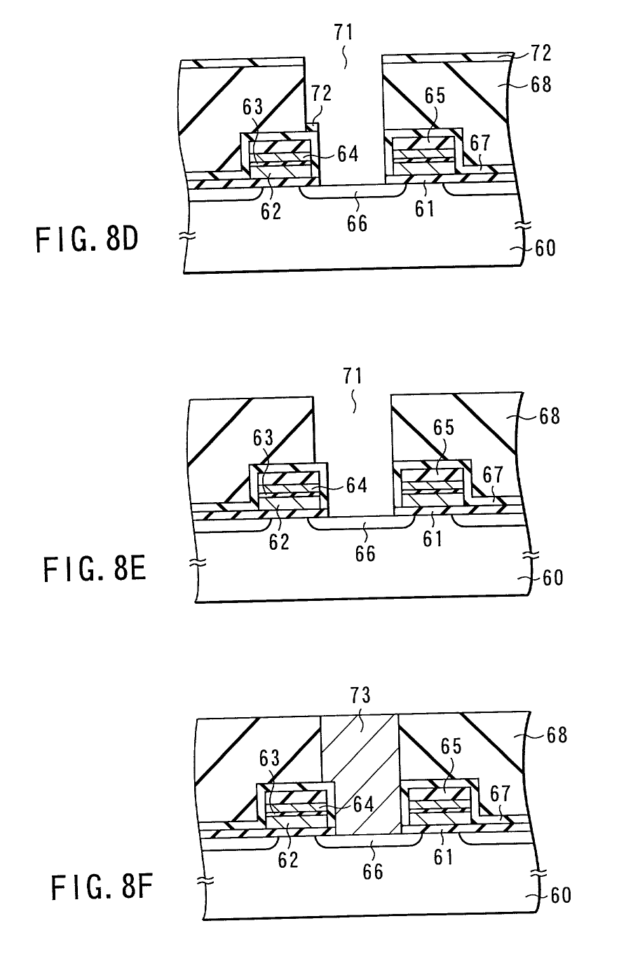

Next, a second embodiment of manufacturing a semiconductor device will be explained with reference to FIGS. 8A to 8F which illustrate one example of the method of manufacturing a contact plug of DRAM where an SAC (Self Align Contact) technique is utilized.

First of all, as shown in FIG. 8A, a gate insulating film 61 made of SiO₂ film is formed on a semiconductor substrate 60 (having a cell capacitor and an element isolation region formed thereon) by means of a hydrogen combustion oxidation method. Then, a polycrystalline silicon film 62 is deposited on this gate insulating film 61 by means of the CVD method. Then, a SiO₂ film 63 is formed on the polycrystalline silicon film 62 by means of the CVD method or oxidation method. Thereafter, W (tungsten) film is formed on the SiO₂ film 63 and heat-treated to silicide the W film, thereby forming a WSi film 64. The SiO₂ film 63 is formed very small in thickness and is designed to prevent the dissipation of W from the WSi film 64. Furthermore, an SiN film 65 is formed on the WSi film 64. Thereafter, the polycrystalline silicon film 62, the SiO₂ film 63, the WSi film 64 and the SiN film 65 are subjected to a patterning process by making use of a lithographic technique and an etching to thereby form a desired pattern, thus forming a gate electrode. Then, an impurity is introduced into the semiconductor substrate 60 by means of an ion implantation technique, thereby forming an impurity diffusion layer 66 which is subsequently turned into source and drain regions. By the way, the source electrode of cell transistor to be disposed in the memory cell region is formed so as to contact with the storage node electrode of the aforementioned cell capacitor. On this occasion, the impurity is introduced concurrently into the gate electrode. Then, the impurity thus introduced is activated by means of a heat treatment, thereby forming a cell transistor of DRAM and an MOS transistor of peripheral circuit region.

Thereafter, an SiN film 67 and an interlayer insulating film 68 made of a BPSG (Boron Phosphorous Silicate Glass) film are formed all over the upper surface of the resultant substrate by means of the CVD method, the surface of the interlayer insulating film 68 thus formed being subsequently flattened by means of a CMP (Chemical Mechanical Polishing) method.

Then, for the purpose of forming a contact hole for making contact with the impurity diffusion layer 66, an ARC 69 is formed on the interlayer insulating film 68, and then, a resist 70 is formed on the ARC 69. Thereafter, the resist 70 is patterned by means of a PEP to form a pattern for forming a contact hole.

Then, as shown in FIG. 8B, by making use of this patterned resist 70 as a mask, the ARC 69 and the interlayer insulating film 68 are etched away by means of the RIE method to thereby form a contact hole 71 having a depth reaching the SiN film 67. An F-based gas such as CF₄ and C₂F₆, or an H—F-based gas such as CHF₃ and a mixture of CHF₃ and H₂, which are conventionally employed, can be employed as an etching gas in this RIE. Since the SAC technique where the SiN film 67 is utilized as a stopper is employed in this step, it becomes possible to perform an etching of high selectivity.

Thereafter, the resist 70 and the ARC 69 are removed as shown in FIG. 8C by means of ashing and wet etching which is designed to remove organic materials. As for the etchant to be employed in this wet etching, a mixed solution comprising H₂SO₄, H₂O₂ and H₂O can be employed for instance.

Then, for the purpose of making contact with the impurity diffusion layer 66, the SiN film 67 and the gate insulating film 61, which are disposed at the bottom of the contact hole 71 and at between neighboring electrodes, are etched away by means of the RIE method. On this occasion, a mixed gas consisting of CH₂F₂, CF₄ and Ar for instance can be employed as an etching gas. The mixing ratio of these CH₂F₂, CF₄ and Ar may be 10 sccm, 30 sccm and 160 sccm, respectively, wherein the pressure inside the chamber 21 may be set to 50 mTorr and a high-frequency power may be set to 300W. By making use of this mixed gas under the aforementioned conditions, only the SiN film 67 and the gate insulating film 61 which are disposed at the bottom of the contact hole 71 can be etched away, while allowing the reaction products 72 to be deposited on the interlayer insulating film 68 as well as on the SiN film 67 formed on the gate electrode disposed inside the contact hole 71 as shown in FIG. 8D. Therefore, it is now possible to form the contact hole 71 having a depth reaching the impurity diffusion layer 66 by simply exchanging the etching gas in the etching process by making use of the ordinary RIE method.

Thereafter, the reaction products 72 thus deposited are removed as shown in FIG. 8E by means of ashing and wet etching.

Subsequently, as shown in FIG. 8F, the contact hole 71 is filled with polycrystalline silicon for instance, and then, the resultant surface is flattened by means of the CMP to thereby form a contact plug 73. By the way, this contact plug 73 may be constituted by a multi-layer structure consisting of Ti (titanium) film and W film for instance.

According to the aforementioned manufacturing method, the SiN film 67 and the gate insulating film 61, which are disposed between neighboring electrodes, are etched away by means of the RIE method wherein a mixed gas containing CH₂F₂ is employed as an etching gas. Namely, it is possible through the employment of this etching gas to selectively etch only these SiN film 67 and gate insulating film 61, which are disposed between the gate electrodes. Therefore, it is no longer necessary to cover the regions with a mask excluding the regions which are disposed between the gate electrodes, thereby making it possible to simplify the manufacturing process of the DRAM, to reduce the manufacturing cost and to improve the yield.

According to this embodiment, for the purpose of making the sidewall of the SiN film 67 more perpendicular as well as for the purpose of uniformly etching the SiN film 67 disposed at the bottom of the contact hole 71, a mixed gas comprising a C-containing gas (CF₄), Ar (argon) (employed as a diluent) and CH₂F₂ is employed as an etching gas. However, it is of course possible to employ an etching gas consisting only of CH₂F₂ gas.

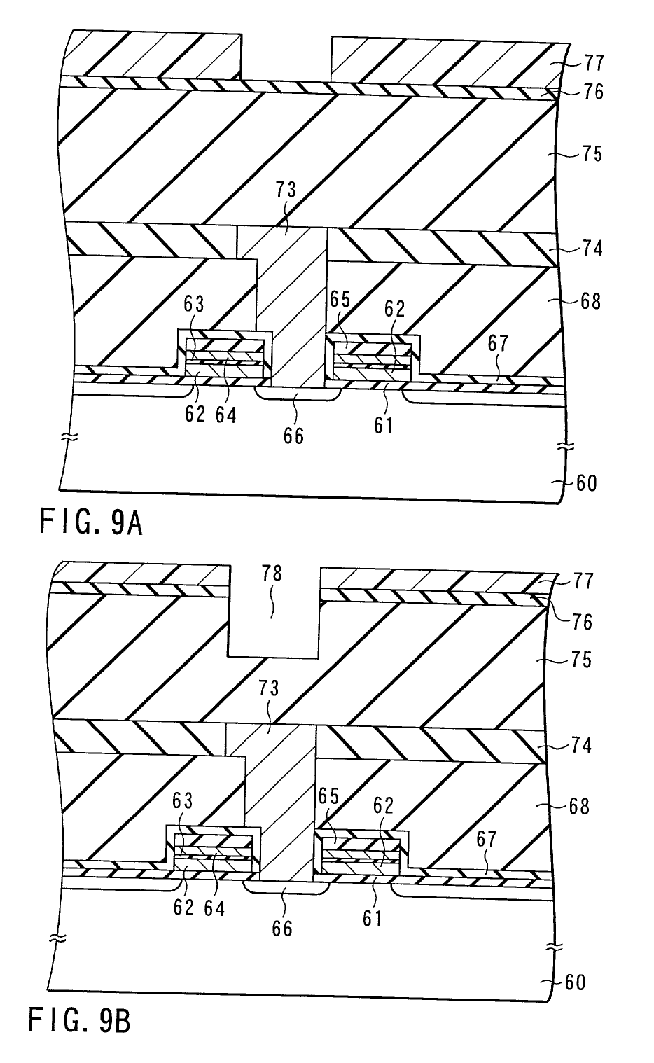

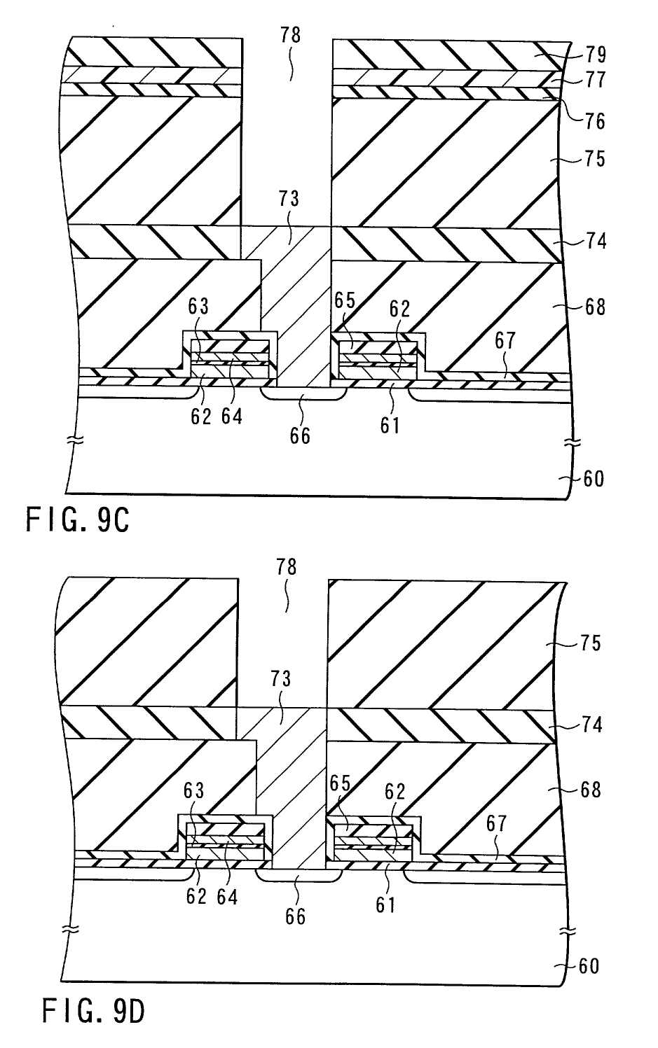

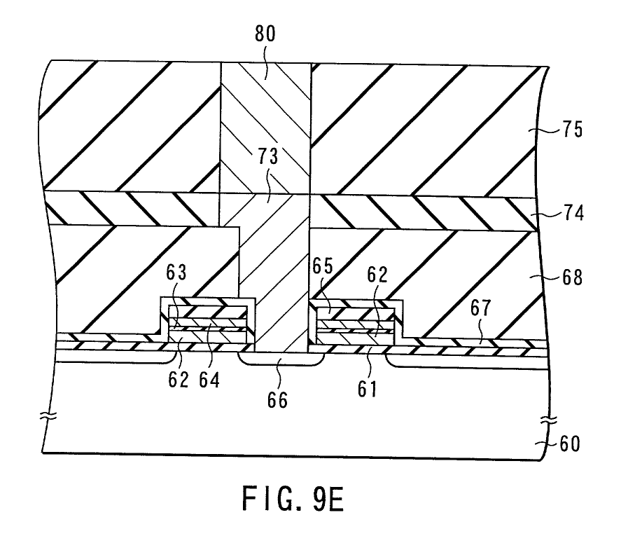

Next, a third embodiment of manufacturing a semiconductor device will be explained with reference to FIGS. 9A to 9E which illustrate one example of the method of manufacturing a contact plug of DRAM.

First of all, as shown in FIG. 9A, in the same manufacturing process as employed in the aforementioned second embodiment, an MOS transistor is formed in the peripheral circuit region. Then, an interlayer insulating film 68 made of BPSG film is formed so as to cover the MOS transistor, and a SiO₂ film 74 is formed on the interlayer insulating film 68 by means of the CVD method using TEOS (Tetraethylorthosilicate: Si(OC₂H₅)₄). Thereafter, the contact hole having a depth reaching the impurity diffusion layer 66 disposed between neighboring gate electrodes is formed and then filled with a metal for instance to form a buried contact plug 73. The level where the SiO₂ film 74 is located is the same with that at which a bit line is to be formed in the memory cell region, so that the contact plug 73 of the peripheral circuit region may be formed taking advantage of the wiring layer of the bit line. Additionally, another interlayer insulating film 75 is formed on the SiO₂ film 74 and the contact plug 73.

Then, for the purpose of forming a contact hole in the interlayer insulating film 75 of the peripheral circuit region for making contact with the contact plug 73, an ARC 76 and a resist 77 are formed on the interlayer insulating film 75. Thereafter, the resist 77 is patterned by means of a PEP to form an opening corresponding to the contact plug 73.

Then, as shown in FIG. 9B, by making use of this patterned resist 77 as a mask, the interlayer insulating film 75 is etched away by means of the RIE method. An F-based gas such as CF₄ and C₂F₆, or an H—F-based gas such as CHF₃ and a mixture of CHF₃ and H₂, which are conventionally employed for etching SiO₂, can be employed as an etching gas in this RIE.

However, since this interlayer insulating film 75 is large in thickness, if a contact hole is to be formed by means of the RIE using an ordinary gas that has been conventionally employed, the resist 77 and the ARC 76 may be etched to such a degree that the mask may be destroyed in the middle of the RIE.

Therefore, the etching gas is replaced by CH₂F₂ at the moment when the mask is completely or nearly vanished, the etching being continued with this CH₂F₂. When the etching is performed with the employment of this CH₂F₂ gas, only the interlayer insulating film 75 is selectively etched, while allowing reaction products 79 such as C and CF to deposit on the resist 77. It is of course possible to employ this CH₂F₂ throughout the entire process of the etching using the RIE for forming the contact hole 78. However, in view of the etching rate, it would be most efficient to perform the RIE in two stages, i.e. an F-based gas, or an H—F-based gas such as CHF₃ and a mixture of CHF₃ and H₂ that has been conventionally employed being employed at the first stage, and CH₂F₂ gas being employed at the second stage.

Thereafter, the resist 77, the ARC 76 and the reaction products 79 that have been deposited on the resist 77 are removed as shown in FIG. 9D by means of ashing and wet etching.

Then, by means of sputtering, a TiN film and a W film are deposited on the surface of the resultant substrate to thereby fill the contact hole 78, which has been formed in the previous step, with these films, the resultant surface being subsequently flattened by means of the CMP to form a contact hole 80 as shown in FIG. 9E.

According to the aforementioned manufacturing method, the etching on the occasion of forming a contact hole in the interlayer insulating film 75 is performed by means of the RIE method employing CH₂F₂ as an etching gas. As a result, it is possible to enable the etching to take place only at the regions which are desired to be etched, while not allowing the etching to proceed at the surface of mask. As a result, the film thickness of the mask can be set to such a minimum thickness that enables the contact hole to be formed.

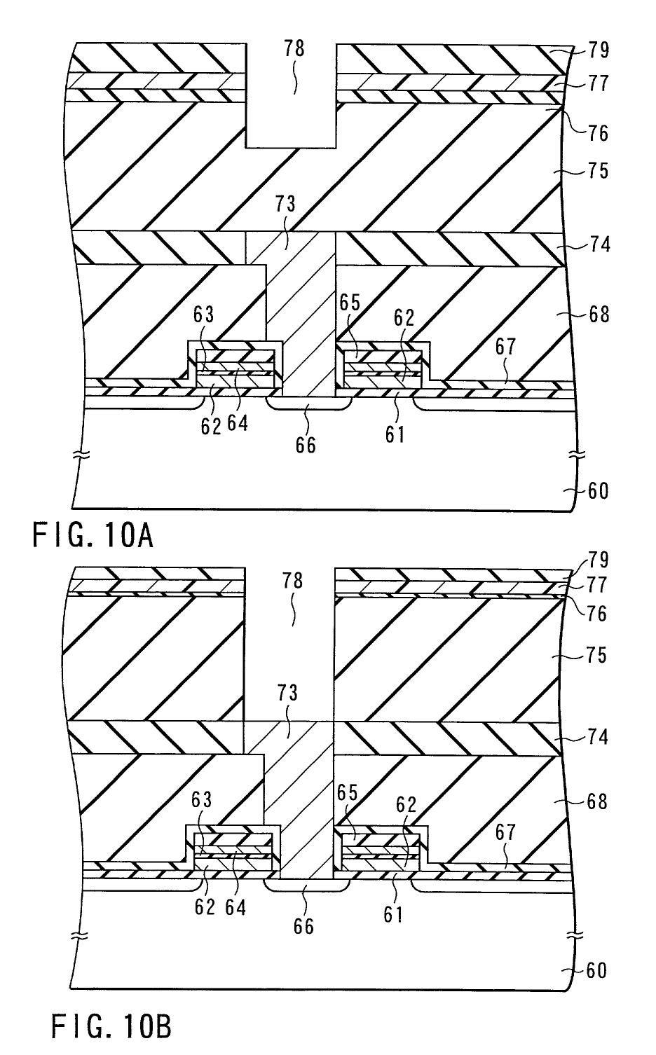

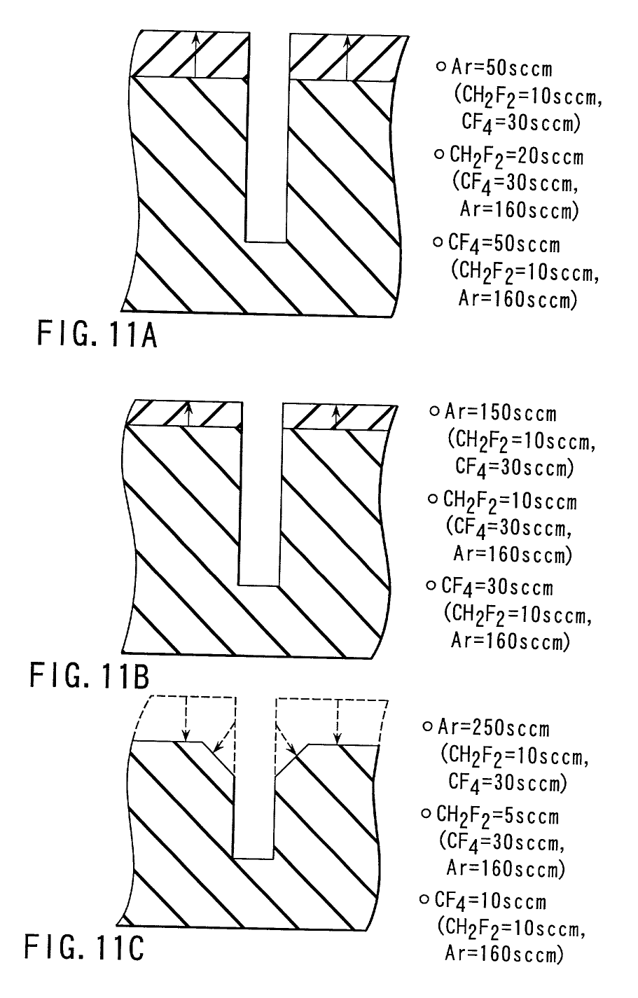

FIGS. 10A and 10B are cross-sectional views illustrating in sequence the manufacturing process of the contact plug for a DRAM, representing a modified example of the aforementioned embodiment.

Namely, as shown in FIG. 10A, CH₂F₂ is employed as an etching gas from the beginning in the process of forming a contact hole in the interlayer insulating film 75 by means of the RIE. In this case, the reaction products 79 are allowed to deposit on the surface of the resist 77 simultaneous with the formation of the contact hole 78.

Then, after the reaction products 79 are deposited to some degree as shown in FIG. 10B, this CH₂F₂ is replaced by an F-based gas, or an H—F-based gas. Thereafter, the etching is continued with the reaction products 79 being employed as a mask to thereby ultimately form the contact hole 78.

According to this modified manufacturing method, the same effects as obtained in the aforementioned embodiment can be obtained.

According to the aforementioned dry etching methods and manufacturing methods of a semiconductor device, which have been illustrated with reference to these first to third embodiments, CH₂F₂ is employed as an etching gas in the dry etching process such as the RIE process on the occasion of forming a trench or a contact hole. Thus, due to the employment of this etching gas containing CH₂F₂, only the region desired to be etched can be selectively etched, while preventing the etching of the mask which is not desired to be etched and contrary, allowing reaction products from the RIE to be deposited on the mask, thus preventing the etching of the mask. Therefore, even if the aspect ratio is enormously large or even if the film thickness of mask is very thin, it is possible to ensure a sufficiently large or substantially infinitely etching selectivity.

Further, as explained in the aforementioned embodiment, the etching gas to be introduced into the etching chamber during the etching may be constituted by a gas consisting only of CH₂F₂ or consisting of CH₂F₂ and other kinds of gas. Preferable examples of gas to be mixed with CH₂F₂ in this case include CO for instance. Among the elements included in these gases, carbon functions to form a reaction product to be deposited as described above. On the contrary, oxygen included in these gases functions to promote the etching since the C representing one of the unsaturated species is oxidized and removed by the oxygen. Therefore, when CO is added to the etching gas, the effects to be derived from CH₂F₂ can be further promoted. If a mixed gas further comprising a C-containing gas (containing at least one carbon atom in its compound; but which excludes CH₂F₂, the same hereinafter) such as CF₄ or C₄F₈ in addition to CO is employed, the deposition of reaction products can be further promoted. It is also possible to employ O₂ or N2 (nitrogen) as an additional gas in the etching gas. However, since these gases are capable of reacting with the reaction products to thereby remove the reaction products, it is not preferable to excessively employ these additional gases. It is also possible to incorporate Ar or He (helium) into the etching gas for the purpose of diluting the etching gas.

As explained above, it is certainly possible to employ not only the gas consisting only of CH₂F₂ but also the gas consisting of CH₂F₂ and other kinds of gas. However, the content of this CH₂F₂ in the mixed gas should be at least 20%. Further, since carbon in a C-containing gas acts to promote the deposition of reaction products in the case where a mixed gas containing this C-containing gas is employed, the total content of CH₂F₂ and this carbon-containing gas in an etching gas should be at least 20%, and at the same time, the content of CH₂F₂ should be at least 5% based on the total volume of the etching gas.

The reason for this requisite to set the total content of CH₂F₂ and the carbon-containing gas to at least 20% based on the total volume of the etching gas will be explained as follows with reference to FIGS. 11A to 11C. These FIGS. 11A to 11C show respectively the cross-sectional view of a semiconductor device where the RIE was performed using, as an etching gas, a mixed gas consisting of CH₂F₂/CF₄/Ar. By the way, the pressure inside the etching chamber was set to 40 mTorr and the high-frequency power was set to 1000W.

First of all, there will be explained on the experiment wherein the gas flow rates of CH₂F₂ and CF₄ were fixed to 10 sccm and 30 sccm, respectively, and under this condition, the flow rate of Ar was varied.

FIG. 11A shows a case where the flow rate of Ar was set to 50 sccm. Under this gas flow rate condition, since the entire gas flow rate was 90 sccm, the ratio of flow rate which was occupied by these CH₂F₂ and CF₄ gases was 44%. In this case, the etching was allowed to proceed at the bottom of the contact hole, while simultaneously allowing reaction products to deposit on the surface of the semiconductor device, thereby making it possible to enable the etching to proceed with substantially infinite selective ratio.

FIG. 11B shows a case where the flow rate of Ar was set to 150 sccm. In this case, the ratio of flow rate which was occupied by these CH₂F₂ and CF₄ gases became 21% based on the entire flow rate. In this case, although the quantity of reaction products was reduced as compared with that obtained under the condition of FIG. 11A, it was still possible to enable the etching to proceed with substantially infinite selective ratio.

FIG. 11C shows a case where the flow rate of Ar was set to 250 sccm. Under this condition, the ratio of flow rate which was occupied by these CH₂F₂ and CF₄ gases became only 14% based on the entire flow rate. As a result, the etching was allowed to proceed not only at the bottom of the contact hole, but also at the surface of the semiconductor device thereby making it impossible to perform a selective etching.

Next, the results of another experiment will be explained, wherein the gas flow rates of CF₄ and Ar were fixed to 30 sccm and 160 sccm, respectively, and under this condition, the flow rate of CH₂F₂ was varied.

When the gas flow rate of CH₂F₂ was set to 20 sccm, the ratio of flow rate which was occupied by these CH₂F₂ and CF₄ gases was 24% based on the entire flow rate, thereby obtaining the result as shown in FIG. 11A. Namely, it was possible to enable the etching to proceed with substantially infinite selective ratio.

When the gas flow rate of CH₂F₂ was reduced to 10 sccm, the ratio of flow rate which was occupied by these CH₂F₂ and CF₄ gases became 20% based on the entire flow rate, thereby obtaining the result as shown in FIG. 11B. Under this condition, it was still possible to enable the etching to proceed with substantially infinite selective ratio.

Whereas, when the gas flow rate of CH₂F₂ was reduced to 5 sccm, the ratio of flow rate which was occupied by these CH₂F₂ and CF₄ gases became only 18% based on the entire flow rate. As a result, it was impossible to perform a selective etching.

Next, the results of still another experiment will be explained, wherein the gas flow rates of CH₂F₂ and Ar were fixed to 10 sccm and 160 sccm, respectively, and under this condition, the flow rate of CF₄ was varied.

When the flow rate of CF₄ was set to 50 sccm, the ratio of flow rate which was occupied by these CH₂F₂ and CF₄ gases was 27% based on the entire flow rate, thereby obtaining the result as shown in FIG. 11A. Namely, it was possible to enable the etching to proceed with substantially infinite selective ratio.

When the gas flow rate of CF₄ was reduced to 30 sccm, the ratio of flow rate which was occupied by these CH₂F₂ and CF₄ gases became 20% based on the entire flow rate, thereby obtaining the result as shown in FIG. 11B. Even under this condition, it was still possible to enable the etching to proceed with substantially infinite selective ratio.

Whereas, when the gas flow rate of CF₄ was further reduced to 10 sccm, the ratio of flow rate which was occupied by these CH₂F₂ and CF₄ gases became only 11% based on the entire flow rate. As a result, it was impossible to perform a selective etching.

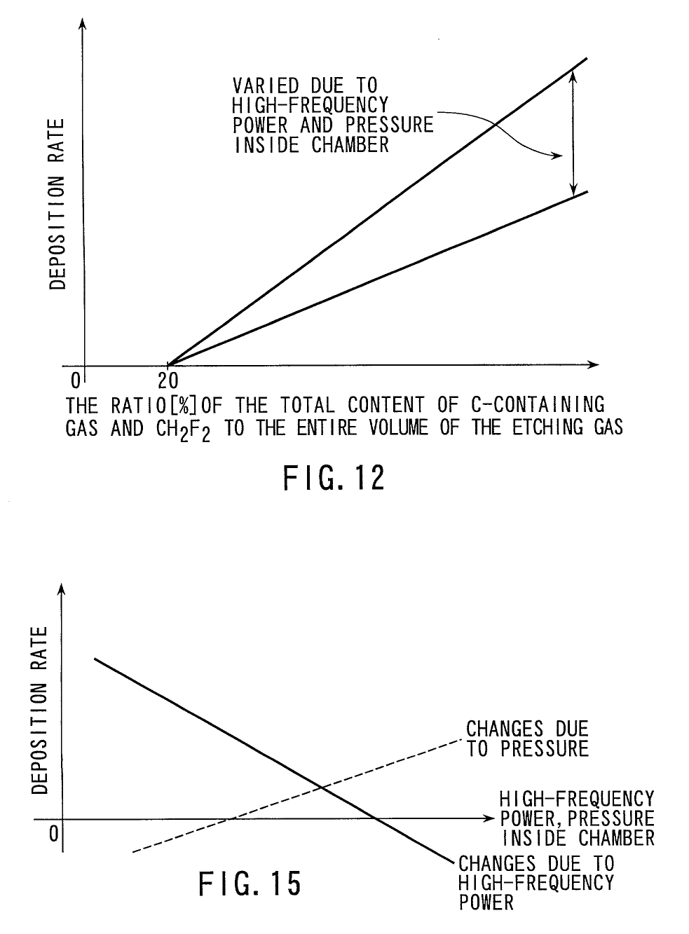

As explained above, when C-containing gas is included in an etching gas, the total content of these CH₂F₂ and CF₄ gases in the etching gas is required to be 20% or more based on the total volume of etching gas. FIG. 12 illustrates this feature as a graph. Namely, FIG. 12 illustrates a relationship between the deposition rate of reaction products and the ratio of the total content of C-containing gas and CH₂F₂ to the entire volume of the etching gas. As seen from FIG. 12, when the total content of C-containing gas and CH₂F₂ to the entire volume of the etching gas became larger than 20%, the deposition of reaction products was initiated, and the deposition rate of reaction products was accelerated as the ratio of the C-containing gas and CH₂F₂ to the entire volume of the etching gas was further increased. Of course, the deposition rate of reaction products can be varied depending on the output of high-frequency power as well as on the pressure inside the etching chamber. However, in any case, this relationship between the total content of C-containing gas and CH₂F₂ to the entire volume of the etching gas would be retained almost in the same manner as shown in FIG. 12.

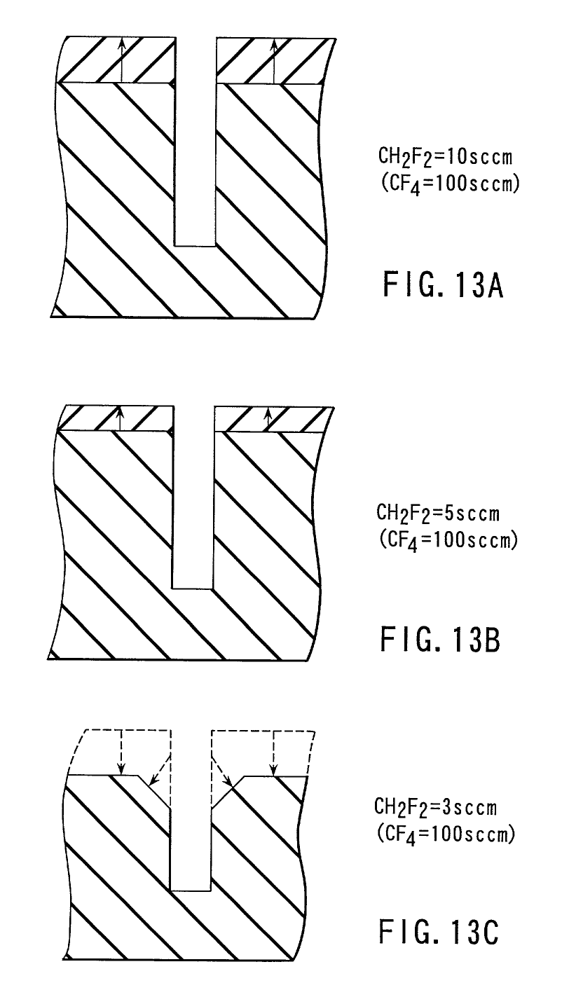

Further, when the C-containing gas is included in the etching gas, the content of CH₂F₂ should be set to 5% or more based on the entire volume of the etching gas. This requisite will be explained below with reference to FIGS. 13A to 13C. These FIGS. 13A to 13C show respectively the cross-sectional view of a semiconductor device where the RIE was performed using, as an etching gas, a mixed gas consisting of CH₂F₂/CF₄. In this case, the flow rate of CF₄ was fixed to 100 sccm, and under this condition, the flow rate of CH₂F₂ was varied. By the way, the pressure inside the etching chamber was set to 40 mTorr and the high-frequency power was set to 500W.

FIG. 13A shows a case where the flow rate of CH₂F₂ was set to 10 sccm. Under this gas flow rate condition, since the entire gas flow rate was 110 sccm, the ratio of the CH₂F₂ in the entire etching gas was 9%. In this case, the etching was allowed to proceed at the bottom of the contact hole, while simultaneously allowing reaction products to deposit on the surface of the semiconductor device, thereby making it possible to enable the etching to proceed with substantially infinite selective ratio.

FIG. 13B shows a case where the flow rate of CH₂F₂ was set to 5 sccm. In this case, the ratio of flow rate which was occupied by CH₂F₂ became 5% based on the entire flow rate. In this case, although the deposition volume of reaction products was greatly reduced as compared with that of FIG. 13A, it was still possible to enable the etching to proceed with substantially infinite selective ratio.

FIG. 13C shows a case where the flow rate of CH₂F₂ was set to 3 sccm. In this case, the ratio of flow rate which was occupied by CH₂F₂ became 3% based on the entire flow rate. Under this condition, the etching was allowed to proceed not only at the bottom of the contact hole, but also at the surface of the semiconductor device thereby making it impossible to perform a selective etching.

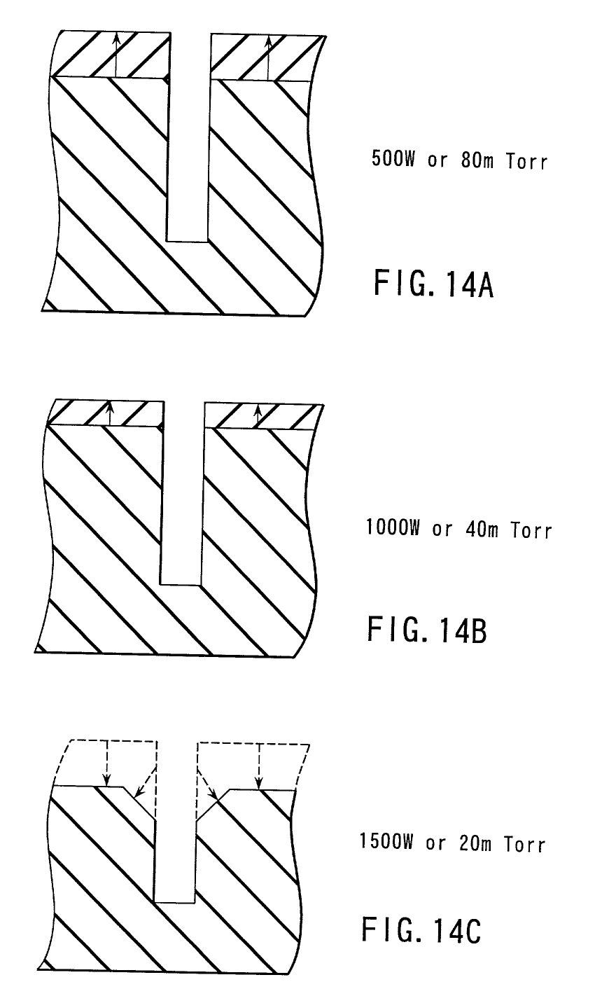

As explained above, it is possible to control the deposition rate of reaction products as well as the etching rate by suitably selecting the gas composition. However, it is also possible to control the deposition rate of reaction products as well as the etching rate by suitably adjusting the radicals and ions to be generated in the plasma which can be effected through the adjustments of the high-frequency power and the pressure inside the etching chamber. This feature will be explained below with reference to FIGS. 14A to 14C. These FIGS. 14A to 14C show respectively the cross-sectional view of a semiconductor device where the RIE was performed using, as an etching gas, a mixed gas consisting of CH₂F₂/CF₄. In this case, the flow rate of CH₂F₂ was set to 40 sccm, and the flow rate of CF₄ was set to 50 sccm.

FIG. 14A shows a case where the high-frequency power was set to 500W or the pressure inside the etching chamber was set to 80 mTorr. Under this condition, the etching was allowed to proceed at the bottom of the contact hole, while simultaneously allowing reaction products to deposit on the surface of the semiconductor device, thereby making it possible to enable the etching to proceed with substantially infinite selective ratio.

FIG. 14B shows a case where the high-frequency power was set to 1000W or the pressure inside the etching chamber was set to 40 mTorr. Under this condition, although the deposition volume of reaction products was greatly reduced as compared with that of FIG. 14A, it was still possible to enable the etching to proceed with substantially infinite selective ratio.

FIG. 14C shows a case where the high-frequency power was set to 1500W or the pressure inside the etching chamber was set to 20 mTorr. Under this condition, the etching was allowed to proceed not only at the bottom of the contact hole, but also at the surface of the semiconductor device thereby making it impossible to perform a selective etching.

FIG. 15 shows these results as a graph. As seen from FIG. 15, it will be understood that the deposition rate of reaction products varies inversely proportionally to the high-frequency power and directly proportionally to the pressure inside the etching chamber. Since ion energy is enhanced as the high-frequency power is increased, the reaction products would be suffered from ion-assisted effects. As a result, the deposition rate of reaction products would be lowered. On the contrary, when the pressure inside the etching chamber is set higher, the ion energy is decreased, so that the deposition rate of reaction products can be increased.

As explained above, according to this invention, by making use of an etching gas comprising at least CH₂F₂ in the execution of the RIE, it become possible to perform the etching with substantially infinite selective ratio. However, it is imperative in this case that CH₂F₂ is included in the etching gas at a ratio of 20% or more, and that when a C-containing gas is additionally included in the etching gas, the total content of the C-containing gas and CH₂F₂ in the etching gas should be 20% or more based on the total volume of etching gas and at the same time, the content of CH₂F₂ should be at least 5% based on the total volume of the etching gas.

In the explanation of the above embodiments, CH₂F₂ has been exemplified as an etching gas. However, the composition of this etching gas is not limited to CH₂F₂ but may be CₙHₓF_{y} (wherein n is an arbitrary integer; and x/y is 0.6 or more) in achieving almost the same effects as explained above. Namely, even if CH₃F or C₃H₅F₃ is substituted for CH₂F₂ as an etching gas, it is possible to obtain almost the same effects as explained above. However, since the deposition rate of reaction products increases as the composition ratio of H (hydrogen) becomes larger and at the same time, the etching rate is more likely to be lowered, the etching gas should be suitably selected depending on the circumstances in the execution of the etching. Further, when the magnitude of the deposition of reaction products becomes excessive, the interior of the vacuum chamber of RIE apparatus may be contaminated. Therefore, it is more preferable to select a condition where the etching rate becomes identical with the deposition rate of reaction products in the region which is not desired to be etched, thereby realizing a situation wherein neither the deposition of reaction products nor the etching can be proceeded in this region. However, the etching rate may not necessarily be controlled so as to make it identical with the deposition rate of reaction products in the region which is not desired to be etched. Namely, what is desired is to balance as much as possible the etching rate with the deposition rate of reaction products, thereby allowing the surface of semiconductor device to be etched slightly, or allowing the reaction products to be deposited slightly.

As for the materials to be etched, they are not limited to SiO₂ and SiN which are exemplified in the aforementioned embodiments but may be Si, organic or inorganic SiO₂. In particular, the organic SiO₂ is attracting many attentions as a material suited for obtaining a film with low dielectric constant, so that this material is suited for forming an interlayer insulating film.

Further, this invention is not limited to the DRAM which has been illustrated in the aforementioned first to third embodiments, but is applicable to other various kinds of semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A dry etching method which comprises the steps of;
forming a recessed portion having an aspect ratio of 0.5 or more in an etching region of a layer to be etched; and
etching a portion of said layer which corresponds to said recessed portion by making use of an etching gas containing CH₂F₂;
wherein said etching gas to be employed in said etching step of said portion of said layer contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

2. The method according to claim 1, wherein said layer to be etched is formed of at least one of the materials selected from the group consisting of an organic SiO₂, an inorganic SiO₂, SiN and Si.

3. The method according to claim 1, wherein said etching gas further comprises a carbon- and oxygen-containing gas wherein said carbon is capable of promoting a deposition rate of reaction products to be generated on the occasion of said etching, and said oxygen is capable of promoting the etching rate.

4. A dry etching method which comprises the steps of;
forming an etching mask on a layer to be etched;
forming a recessed portion having an aspect ratio of 0.5 or more in said etching mask; and
etching a portion of said layer which corresponds to said recessed portion by making use of an etching gas containing CH₂F₂;
wherein said etching gas to be employed in said etching step of said portion of said layer contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

5. The method according to claim 4, wherein said layer to be etched is formed of at least one of the materials selected from the group consisting of an organic SiO₂, an inorganic SiO₂, SiN and Si.

6. The method according to claim 4, wherein said etching gas further comprises a carbon- and oxygen-containing gas wherein said carbon is capable of promoting a deposition rate of reaction products to be generated on the occasion of said etching, and said oxygen is capable of promoting the etching rate.

7. A dry etching method which comprises the steps of;
forming an etching mask on a layer to be etched;
forming a recesses portion reaching through said etching mask to the middle of said layer to be etched, and having an aspect ration of 0.5 or more; and
etching a portion of said layer which corresponds to said recessed portion by making use of an etching gas containing CH₂F₂;
wherein said etching gas to be employed in said etching step of said portion of said layer contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

8. The method according to claim 7, wherein said layer to be etched is formed of at least one of the materials selected from the group consisting of an organic SiO₂, an inorganic SiO₂, SiN and Si.

9. The method according to claim 7, wherein said etching gas further comprises a carbon- and oxygen-containing gas wherein said carbon is capable of promoting a deposition rate of reaction products to be generated on the occasion of said etching, and said oxygen is capable of promoting the etching rate.

10. A method of fabricating a semiconductor device, which comprises the steps of;
forming a first mask on a semiconductor substrate;
forming a second mask on said first mask;
forming a recessed portion having an aspect ratio of 0.5 or more in said second mask;
etching a portion of said first mask which corresponds to said recessed portion by making use of an etching gas containing CH₂F₂; and
etching a portion of said semiconductor substrate which corresponds to said recessed portion to thereby form a trench;
wherein said etching gas to be employed in said etching step of said portion of said first mask contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

11. The method according to claim 10, wherein at least part of said step of forming a trench by etching a portion of said semiconductor substrate is performed using an etching gas containing CH₂F₂;
wherein said etching gas contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

12. The method according to claim 10, wherein said etching gas further comprises a carbon- and oxygen-containing gas wherein said carbon is capable of promoting a deposition rate of reaction products to be generated on the occasion of said etching, and said oxygen is capable of promoting the etching rate.

13. A method of fabricating a semiconductor device, which comprises the steps of;
forming a gate insulating film on a semiconductor substrate;
forming a gate electrode on said gate insulating film;
forming an insulating film on said gate insulating film and on said gate electrode;
forming an interlayer insulating film on said insulating film;
forming a contact hole to a depth to reach a portion of said insulating film which is located between said gate electrodes neighboring to each other by making use of said insulating film as a stopper; and
etching a portion of said insulating film which is disposed between said gate electrodes by making use of an etching gas containing CH₂F₂;
wherein said etching gas to be employed in said etching step of said portion of insulating film which is disposed between said gate electrodes contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

14. The method according to claim 13, which further comprises the step of;
etching said gate insulating film located between said gate electrodes by making use of an etching gas containing CH₂F₂ subsequent to said step of etching said insulating film between said gate electrodes;
wherein said etching gas contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

15. The method according to claim 13, wherein said etching gas further comprises a carbon- and oxygen-containing gas wherein said carbon is capable of promoting a deposition rate of reaction products to be generated on the occasion of said etching, and said oxygen is capable of promoting the etching rate.

16. A method of fabricating a semiconductor device, which comprises the steps of;
forming an interlayer insulating film on a semiconductor substrate;
forming a mask on said interlayer insulating film;
etching said mask to form a desired pattern thereof; and
forming a contact hole by etching said interlayer insulating film by making use of said mask;
wherein at least part of said step of forming a contact hole by etching said interlayer insulating film is performed by an etching employing an etching gas containing CH₂F₂; and said etching gas to be employed in said etching step employing an etching gas containing CH₂F₂ contains 20% or more of CH₂F₂ where carbon-containing gas in said etching gas is constituted by only CH₂F₂, or contains 5% or more of CH₂F₂ where said etching gas contains not only CH₂F₂ but also another kind of carbon-containing gas, a ratio in total of said CH₂F₂ and said another kind of carbon-containing gas in said etching gas being 20% or more.

17. The method according to claim 16, wherein said etching gas further comprises a carbon- and oxygen-containing gas wherein said carbon is capable of promoting a deposition rate of reaction products to be generated on the occasion of said etching, and said oxygen is capable of promoting the etching rate.
